(19) United States
(12) Patent Application Publication
(10) Pub. No.: US 2026/0027595 A1
(43) Pub. Date: Jan. 29, 2026

(54) INGOT PULLER APPARATUS INCLUDING IN-SITU CABLE CLEANER

(71) Applicant: GlobalWafers Co., Ltd., Hsinchu (TW)

(72) Inventors: Yu-Chiao Wu, Frontenac, MO (US); James Dean Eoff, Montgomery City, MO (US); William Lynn Luter, St. Charles, MO (US)

(21) Appl. No.: 19/278,334

(22) Filed: Jul. 23, 2025

Related U.S. Application Data
(60) Provisional application No. 63/675,587, filed on Jul. 25, 2024.

(51) Int. Cl. B08B 5/02; C30B 15/30; C30B 15/32

(52) U.S. Cl. CPC B08B 5/02; C30B 15/30; C30B 15/32

(57) ABSTRACT

An ingot puller apparatus includes a crucible assembly for holding a silicon melt, a crystal puller housing that defines a growth chamber, the crucible assembly being disposed within the growth chamber, a pulling mechanism including a seed cable, and a cleaning tool for cleaning the seed cable. The cleaning tool includes a main body defining a slot that extends through the main body for receiving the seed cable, a nozzle connected to the main body for directing a pressurized fluid at the seed cable, and a discharge conduit connected to the main body for evacuating fluid discharged from the nozzle. The main body is attached to the crystal puller housing.

### CROSS-REFERENCE TO RELATED APPLICATION

This application claims the benefit of U.S. Provisional Patent Application No. 63/675,587, filed Jul. 25, 2024, which is incorporated herein by reference it its entirety.

### FIELD OF THE DISCLOSURE

The field of the disclosure relates to ingot pullers for growing single crystal silicon ingots and, more particularly, to ingot pullers including an in-situ cable cleaner.

### BACKGROUND

Single crystal silicon, which is the starting material for most processes for the fabrication of many electronic components such as semiconductor devices and solar cells, is commonly prepared by Czochralski (CZ) growth methods. In these methods, a polycrystalline source material, such as polycrystalline silicon (“polysilicon”), in the form of solid feedstock material is charged to a quartz crucible and melted, a single seed crystal is brought into contact with the molten silicon or melt, and a single crystal silicon ingot is grown by slow extraction. The single-crystal silicon ingot is typically pulled by a seed cable in the CZ method. The seed cable is connected to a pulling mechanism which lowers and raises the seed cable within the ingot puller apparatus.

During ingot growth, silicon oxides may form in the melt. The silicon oxides are carried from the melt and deposit within the ingot puller apparatus including on the seed cable of the ingot puller apparatus. Other deposits such as carbon may be carried from the melt and may adhere to the seed cable. The deposits that form on the seed cable may fall from the seed cable during ingot growth which may result in loss of zero dislocation growth of the single crystal silicon ingot or cause defects to form in the ingot (e.g., slip or twin lamella). The silicon oxides may be removed from the seed cable periodically to prevent the oxides from falling into the melt. Cleaning operations which contact the seed cable may cause excessive wear and reduced service life of the seed cable.

Accordingly, a need exists for improved systems and methods that facilitate removing contamination from the seed cable during the CZ growth process.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, an ingot puller apparatus includes a crucible assembly for holding a silicon melt, a crystal puller housing that defines a growth chamber, the crucible assembly being disposed within the growth chamber, a pulling mechanism including a seed cable, and a cleaning tool for cleaning the seed cable. The cleaning tool includes a main body defining a slot that extends through the main body for receiving the seed cable, a nozzle connected to the main body for directing a pressurized fluid at the seed cable, and a discharge conduit connected to the main body for evacuating fluid discharged from the nozzle. The main body is attached to the crystal puller housing.

In another aspect, a method of cleaning a seed cable of an ingot puller apparatus includes directing a pressurized fluid through a nozzle of a cleaning tool to the seed cable. The cleaning tool includes a main body attached to a housing of the ingot puller apparatus and the nozzle is connected to the main body. The main body defines a slot that extends through the main body, and the seed cable extends through the slot. The method further includes directing the fluid discharged from the nozzle to a discharge conduit connected to the main body and controlling a pulling mechanism of the ingot puller apparatus to move the seed cable through the slot for cleaning along a length of the seed cable.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic cross-section side view of an ingot puller for forming a single crystal silicon ingot.

FIG. 2 is a schematic view of an example in-situ cable cleaner suitable for use with the ingot puller of FIG. 1.

FIG. 3 is a perspective view showing the cable cleaner of FIG. 2 in isolation.

FIG. 4 is another perspective of the cable cleaner of FIG. 3 showing air flow in the cable cleaner.

FIG. 5 is a partial cross section of the cleaner and air flow shown in FIG. 4.

Corresponding reference characters indicate corresponding parts throughout the drawings.

### DETAILED DESCRIPTION

This disclosure relates to ingot pullers used to grow single crystal ingots, such as single crystal silicon ingots. Example ingot pullers include a housing defining a growth chamber in which a melt of polycrystalline silicon material is contained in a crucible. The ingot pullers also include a receiving chamber or pull chamber into which the ingot is pulled from the melt. A seed cable (also referred to as a pull cable) is lowered through the pull chamber into the growth chamber, and is attached to a seed crystal that is contacted with the melt to initiate crystal growth. The seed cable and the ingot are then pulled into the pull chamber, from which the ingot can be removed once fully grown. The ingot pullers of this disclosure also include an in-situ cleaning tool. In some embodiments, the cleaner is installed on the top of the pull chamber. In some embodiments, the seed cable is cleaned automatically when the receiving chamber is disconnected from vacuum using the cleaning tool. In some embodiments, the cleaning tool includes two opposite air nozzles that are used to blow the dust and particles away from the seed cable, and two opposite vacuum ports that are used to collect the dust and particles.

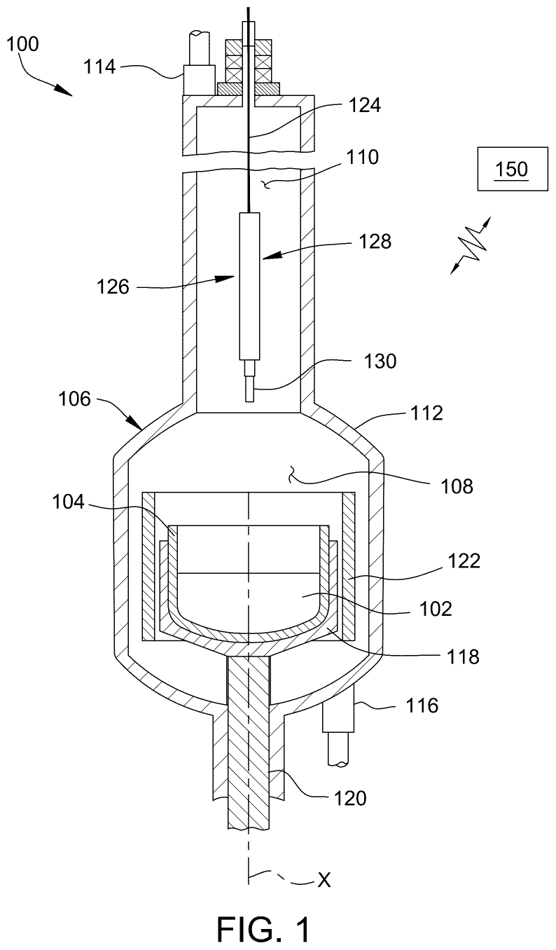

Referring to FIG. 1, an ingot pulling apparatus or ingot puller is shown schematically and is indicated generally at 100. The ingot puller 100 is used to produce single crystal (i.e., monocrystalline) ingots of semiconductor or solar-grade material such as, for example, single crystal silicon ingots. In some embodiments, the ingot is grown by the so-called Czochralski (CZ) process in which the ingot is withdrawn from a silicon melt 102 held within a crucible 104 of crystal puller 100. In some embodiments, the ingot is grown by a batch CZ process in which polycrystalline silicon is charged to the crucible 104 in an amount sufficient to grow one ingot, such that the crucible 104 is essentially depleted of silicon melt 102 after the growth of the one ingot. In other embodiments, the ingot is grown by a continuous CZ (CCZ) process in which polycrystalline silicon is continually or periodically added to crucible 104 to replenish silicon melt 102 during the growth process. The CCZ process facilitates growth of multiple ingots pulled from a single melt 102. Embodiments of the subject matter described herein are not limited to a particular crystal growth process, however. For example, in other embodiments, a polycrystalline silicon ingot may be grown using a directional solidification process for solar applications.

The ingot puller 100 includes a housing 106 that defines a crystal growth chamber 108 and a pull chamber 110 having a smaller transverse dimension than the growth chamber 108. The growth chamber 108 has a generally dome shaped upper wall 112 transitioning from the growth chamber 108 to the narrowed pull chamber 110. The ingot puller 100 includes an inlet port 114 and an outlet port 116 which may be used to introduce and remove a process gas to and from the ingot puller 100 during crystal growth.

The crucible 104 within the ingot puller 100 contains the silicon melt 102 from which a silicon ingot is drawn. The crucible 104 may be made of quartz or fused silica, which has a high melting point and thermal stability and is generally non-reactive with molten silicon in melt 102. It should be understood that the crucible 104 may be made from other materials in addition to quartz without departing from the scope of the present disclosure. For example, the quartz crucible 104 may be made from a composite material that includes silica and an additional material, for example, silicon nitride or silicon carbide.

The silicon melt 102 is obtained by melting polycrystalline silicon charged to the crucible 104. In continuous systems, a feed system (not shown) is used for feeding solid feedstock material into the crucible assembly 104 and/or the melt 102. The crucible 104 is positioned within and supported by a susceptor 118 that is in turn supported by a rotatable shaft 120. Susceptor 118 and rotatable shaft 120 facilitate rotation of the crucible 104 about a central longitudinal axis X of the ingot puller 100. Susceptor 118 and crucible 104 are also vertically moveable in some embodiments. Rotational and vertical movement of the susceptor 118 and crucible 104 may be controlled throughout the ingot growth process by a controller 150 of the ingot puller 100.

A heating system 122 (e.g., one or more an electrical resistance heaters) surrounds the susceptor 118 and crucible 104 and supplies heat by conduction through the susceptor 118 and crucible 104 for melting the silicon charge to produce the melt 102 and/or maintaining the melt 102 in a molten state. The heating system 122, or heater 122, can include a bottom heater below the crucible 104 and a side heater laterally adjacent the crucible 104. Additionally or alternatively, the heater 122 extends from the side to below the susceptor 118 and crucible 104.

The heating system 122 is controlled by the controller 150 so that the temperature of the melt 102 is precisely controlled throughout the pulling process. For example, the controller 150 may control electric current provided to the heating system 122 to control the amount of thermal energy supplied by the heating system 122. The controller 150 may control the heating system 122 so that the temperature of the melt 102 is maintained above about the melting temperature of silicon (e.g., about 1412° C.). For example, the melt 102 may be heated to a temperature of at least about 1425° C., at least about 1450° C. or even at least about 1500° C. Insulation (not shown) surrounding the heating system 122 may reduce the amount of heat lost through the housing 106. The ingot puller 100 may also include a heat shield assembly (not shown) above the surface of melt 102 for shielding the ingot from the heat of the crucible 104 to increase the axial temperature gradient at the solid-melt interface.

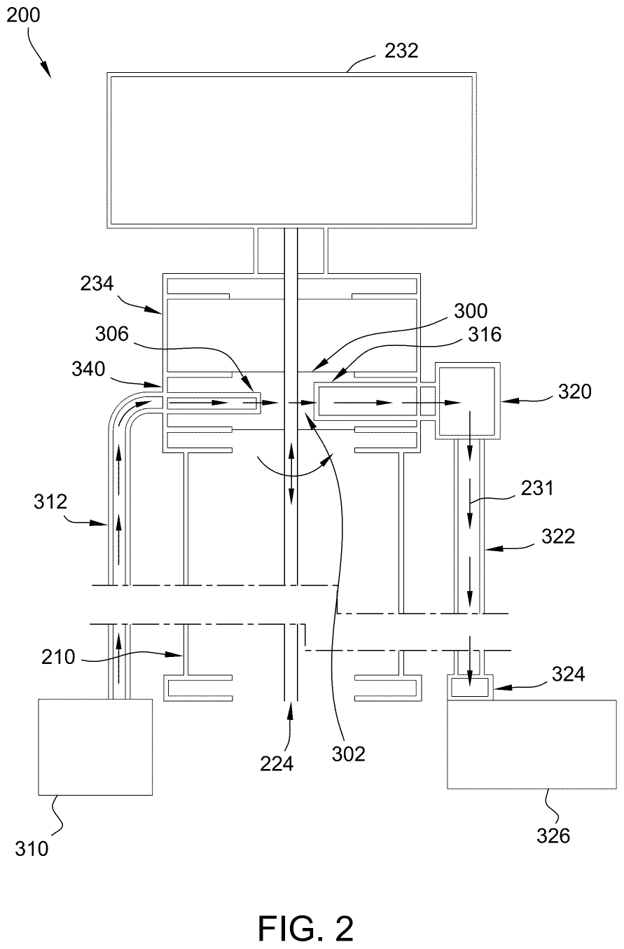

A pulling mechanism or pull head (see FIG. 2) is attached to a seed cable 124, or a seed cable, that extends down from the mechanism. The mechanism is capable of raising and lowering the seed cable 124 and rotating the seed cable 124. The ingot puller 100 may have a pull shaft rather than a wire, depending upon the type of puller. The seed cable 124 terminates in a pulling assembly 126 that includes a seed crystal chuck 128 which holds a seed crystal 130 used to grow the silicon ingot. In growing the ingot, the pulling mechanism lowers the seed crystal 130 until it contacts the surface of the silicon melt 102. Once the seed crystal 130 begins to melt, the pulling mechanism slowly raises the seed crystal up through the growth chamber 108 and pull chamber 110 to grow the single crystal ingot. The speed at which the pulling mechanism rotates the seed crystal 130 and the speed at which the pulling mechanism raises the seed crystal (i.e., the pull rate v) are controlled by the controller 150. As the seed crystal 130 is slowly raised from the melt 102, silicon atoms from the melt 102 align themselves with and attach to the seed crystal 130 to form an ingot.

A process gas (e.g., argon) is introduced through the inlet port 114 into the growth chamber 108 and pull chamber 110 and is withdrawn through the outlet port 116. The process gas creates an atmosphere within the housing and the melt and atmosphere form a melt-gas interface. The outlet port 116 is in fluid communication with an exhaust system (not shown) of the ingot puller.

The ingot puller 100 also includes the controller 150 communicatively connected to various components of the puller 100, including the heater 122, the pulling mechanism, a susceptor/crucible rotatable drive unit, a susceptor/crucible lift unit, as well as other auxiliary components of the puller 100 such as temperature sensors (e.g., pyrometers), optical units (e.g., IR cameras), a cooling jacket, among others. Although a single controller 150 is shown and described, the controller 150 may include multiple controllers 150 that may be centralized or decentralized. The controller 150 controls various aspects and parameters of the ingot puller 100 during the ingot growth process 100. For example, the controller 150 controls electric current supplied to the heater 122 to control the amount of thermal energy supplied by the heater. The controller 150 also controls operation of the pulling mechanism and the movement of the crucible 104. For example, the controller 150 may control a pull rate of the seed cable 124, a rotation rate of the seed crystal 130, a rotation rate of the crucible 104, and/or a vertical position of the crucible 104 in the growth chamber 108.

The controller 150 may receive feedback and monitored process information from one or more sensors, such as pyrometers, IR cameras, or another suitable sensor type, for continuous, periodic, or intermittent monitoring of conditions within the growth chamber 108, such as the temperature of the melt 102, temperature at the solid-melt interface between the melt 102 and a growing crystal, a surface level of the melt 102 (i.e., a vertical position of the melt surface), the temperature of the growing crystal, among other information. The sensors may be communicatively connected with controller 150 to provide feedback information about the ingot growth process to the controller 150.

The controller 150 may include a communication interface to communicatively couple the controller 150, via one or more connections 151, to one or more components of the ingot puller 100. For example, the one or more connections 151 may communicatively couple the controller 150 to the heater 122, the pulling mechanism, the crucible drive unit, the crucible lift unit, sensors (e.g., pyrometers and IR cameras), the cooling jacket, and/or other components of the ingot puller 100. The communication interface may include, for example, a wired or wireless network adapter and/or a wireless data transceiver for use with a mobile telecommunications network. In this way, the one or more connections 151 may communicatively couple the controller 150 to the one or more components of the ingot puller 100 via a wired and/or wireless connection.

The illustrated ingot puller apparatus 100 is an example and the cleaning tool 300 described below may generally be used to clean the seed cable 124 of any ingot puller apparatus that includes such a seed cable 124. The seed cable 124 may include a wire or a series of wires (e.g., twisted wires) that combine to form a cable. The seed cable 124 may be made of tungsten, such as twisted tungsten wires.

FIG. 2 shows a schematic of an alternative ingot puller apparatus 200 including a cleaning tool 300. The ingot puller apparatus 200 is substantially the same as the ingot puller apparatus 100, except that the ingot puller apparatus 200 includes the cleaning tool 300 installed in-situ within the apparatus 200. The ingot puller apparatuses 100, 200 are an example and the cleaning tool 300 described below may generally be used to clean the seed cable 224 of any ingot puller apparatus that includes such a seed cable 224. The seed cable 224 may include a wire or a series of wires (e.g., twisted wires) that combine to form a cable. The seed cable 224 may be made of tungsten, such as twisted tungsten wires.

As shown in FIG. 2, the cleaning tool 300 is positioned between the pull mechanism or pull head 232, which is used to lower and raise and rotate the seed cable 224, and the pull chamber 210 (also referred to as a receiving chamber). In the example embodiment, the cleaning tool 300 is attached to the pull chamber 210 at a top end of the pull chamber 210. In other embodiments, the cleaning tool 300 may be at least partially positioned within the pull chamber 210. A damper 234 is positioned between the pull head 232 and the cleaning tool 300. In the example, the damper 234 is a tuned mass damper or “earthquake damper” configured to dissipate the energy generated from seismic waves in event of an earthquake. In other embodiments, the apparatus 200 does not include the damper 234.

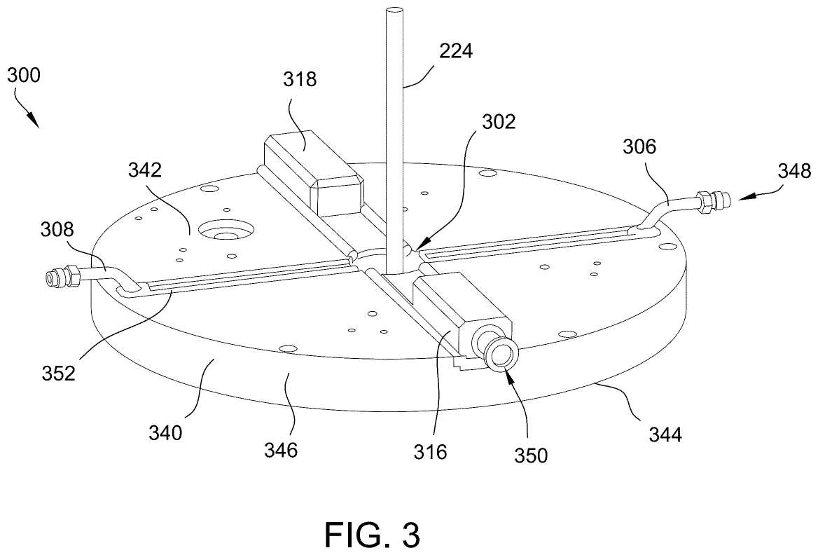

The cleaning tool 300 defines a central slot 302 therein and is positioned within the apparatus such that the slot 302 is aligned longitudinally with the seed cable 224. The seed cable 224 extends through the slot 302 without contacting any portions of the cleaning tool 300. The cleaning tool 300 includes one or more supply nozzles 306, 308 (two in the example embodiment as shown in FIG. 3) for directing a pressurized fluid at the seed cable 224. Generally, any supply nozzle that directs pressurized fluid toward the seed cable 224 may be used (e.g., that increases the speed of the fluid). While a first nozzle 306 and second nozzle 308 are shown in the illustrated embodiment, in other embodiments a single nozzle or more than two nozzles may be used.

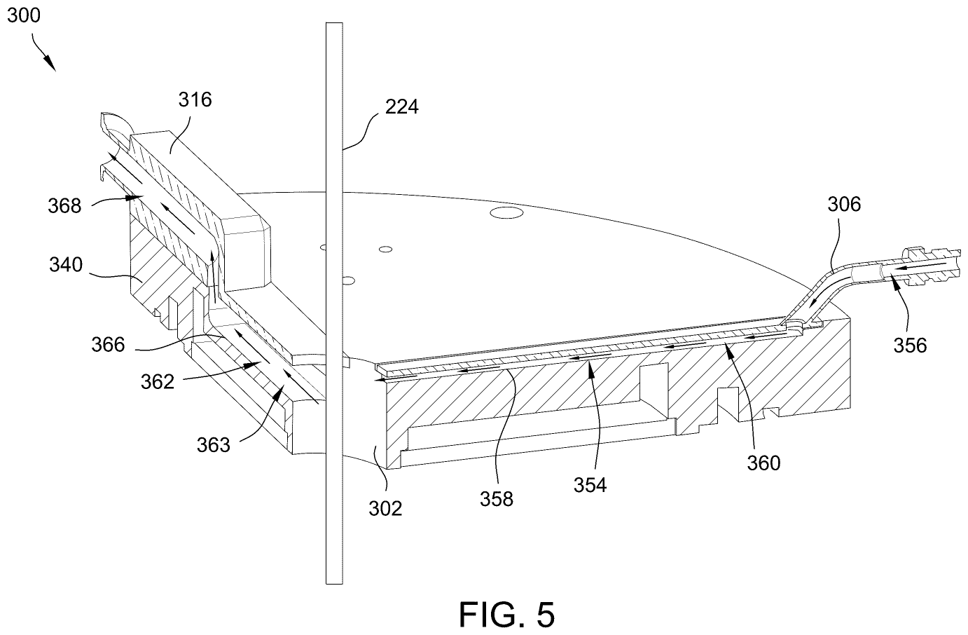

Each nozzle 306, 308 is connected to a source of pressurized fluid (e.g., pressurized air or other gas such as argon or nitrogen), referred to herein as a fluid source 310 by a supply tube 312. At least one of the fluid source 310, the supply tube 312, and the nozzle 306 may include a valve (not shown), controlling the flow of fluid to the seed cable 224. In the example embodiment, the fluid source 310 includes the valve. The cleaning tool 300 may include end fitting connectors 314 (FIG. 5) to connect to the supply tube 312 and/or the source of pressurized fluid to the supply nozzles 306, 308. Pressurized fluid is directed toward the seed cable 224 through the nozzles 306, 308. The pressurized fluid may be controlled by valves in one or more supply conduits integrated into the source of pressurized fluid and/or in the supply tube 312.

After contact with the seed cable 224, the fluid (including carried debris removed from the seed cable 224) enters one or more discharge conduits 316, 318 which evacuates (e.g., carries away) the fluid discharged from the nozzles 306, 308 through a discharge tube 322. A selectively controllable valve 320 connects the discharge conduit 316 to the discharge tube 322. In the example embodiment the valve 320 is an angle valve and the discharge conduit 316 and discharge tube 322 are oriented generally perpendicular to one another. The valve 320 is controlled to isolate the pull chamber 210 when the pull chamber 210 is under vacuum (e.g., during an ingot pulling operation). When the pull chamber 210 is not under vacuum, the valve 320 is opened prior to initiating a cleaning operation of the seed cable 224 using the cleaning tool 300. The discharge tube 322 includes a pipe adapter 324 for connecting the discharge tube 322 to any suitable receptacle (not shown). In the example embodiment, the discharge tube 322 is in fluid communication with a vacuum generator 326 (e.g., a vacuum pump). The vacuum generator 326 is configured to generate a negative pressure in the discharge tube 322 for directing air flow through the cleaning tool 300 along the direction arrows 231, as indicated in FIG. 2. In the view of FIG. 2, the discharge conduit 316 and supply nozzle 306 are shown as being positioned on opposed sides of the cleaning tool 300 for simplicity.

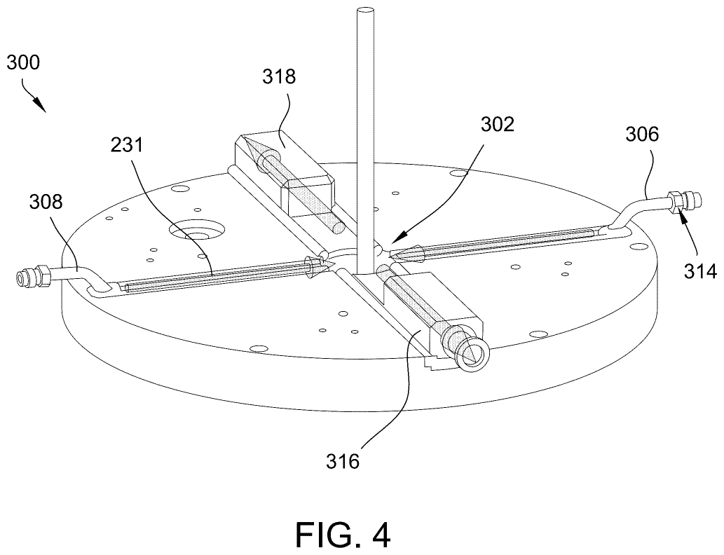

As shown in FIG. 4, in the example embodiment, the discharge conduits 316, 318 are each oriented perpendicular to the supply nozzles 306, 308, such that the airflow 231 is turned within the slot 302.

In operation of the seed cleaner tool 300, air will go into the cleaner through the supply tube 312 and supply nozzle 306 and then blow onto the seed cable 224 extending through the slot 302. The dust and particles on the seed cable 224 are blown off and collected into the discharge conduits 316, 318, exiting into the discharge tube 322 via the opened valve 320. The pull head 232 raises/lowers and rotates the seed cable 224 up and down, which allows for cleaning the whole seed cable 224. The relative positioning between the supply nozzles 306, 308 and discharge conduits 316, 318 also causes the air to flow in multiple directions (see FIGS. 4 and 5) at the slot 302 and seed cable 224, which may further induce blowing contaminants off the seed cable 224.

The controller 150 (shown in FIG. 1) is connected in communication with one or more of the pull head 232, the valve 320, the vacuum generator 326, the fluid source 310, the cleaning tool 300, and the pull head 232, and is configured to control the ingot puller apparatus 200 to automatically perform the seed cable cleaning operation. For example, the controller 150 is configured to control the cleaning tool 300 to direct the pressurized fluid to the seed cable 224 by controlling a valve (not shown) on the fluid source 310, supply tube 312, and/or nozzle 306 to open. The controller 150 further controls the vacuum generator 326 to generate a negative pressure and opens the discharge valve 320. Prior to initiating the cleaning process, the controller 150 may control a pressurization sequence of the ingot puller apparatus 200 if the pressure within the pull chamber 210 is at vacuum prior to cleaning the seed cable 224. The controller 150 is further configured to control the pull head 232 during the cleaning process to move the seed cable 224 through the slot 302 to allow for cleaning along a length of the seed cable 224.

The cleaning tool is shown isolated with the seed cable 224 in FIGS. 3-5. The cleaning tool 300 includes a main body 340 having a disc shape and including a first end wall 342, a second end wall 344, and a sidewall 346 extending from the first end wall 342 to the second end wall 344. The slot 302 is positioned at approximately a radial center of the main body 340 and the seed cable 224 extends fully through the slot 302.

The cleaning tool 300 includes two supply nozzles 306, 308 and two discharge conduits 316, 318. The supply nozzles 306, 308 each include an air inlet 348 and the discharge conduits 316, 318 each include an air outlet 350. The supply nozzles 306, 308 and discharge conduits 316, 318 are each attached to the main body and are positioned at least partially recessed on the first end wall 342. Seals 352 extend around an interface between each of the supply nozzles 306, 308/discharge conduits 316, 318 and the main body 340. The supply nozzles 306, 308 and discharge conduits 316, 318 are each oriented radially about the main body 340 and extend toward the slot 302. The supply nozzles 306, 308 and discharge conduits 316, 318 arranged in alternating manner in a circumferential direction, with each supply nozzle 306 being positioned between the two discharge conduits 316, 318 at an approximately 90 degree offset. As shown in FIG. 4, the air supply is directed toward the seed cable from opposed directions and is redirected within the slot 302 around the seed cable 224 and to one of the two opposing discharge conduits 316, 318.

Referring to FIG. 5, the first nozzle 306 and the main body 340 collectively define a supply channel 354 through which the incoming supply air flows. A first section 356 of the supply channel 354 is defined entirely within the first nozzle 306 and a second section 360 of the supply channel 354 is defined between the first nozzle 306 and a radially extending first recessed surface 358 of the main body 340. In the example, a cross-sectional area of the supply channel 354 in the second section 360 is less than a cross-sectional area of the supply channel 354 in the first section 356, causing the pressurized fluid to increase in pressure for discharge at the seed cable 224.

As shown in FIG. 5, the discharge conduit 316 and the main body 340 collectively define a discharge channel 362 through which the discharged air flows during cleaning. A first section 363 of the discharge channel 364 is defined between the discharge conduit 316 and a second radially extending recessed surface 366 of the main body 340. The second section 368 of the discharge channel 364 is defined entirely within the discharge conduit 316

Additionally or alternatively, the air supply channels 354 and discharge channels 364 can be defined wholly by conduits, pipes, or tubes that are attached to or secured relative to the disk.

The systems and methods of the present disclosure can be implemented in any suitable CZ growth process, such as CZ growth processes used to grow single crystal silicon ingots.

The ingot pullers of the present disclosure provide advantages such as reducing the potential for slip and twin while pulling a single crystal ingot from a melt, and thereby increasing yield and throughput and reducing costs. The advantages are enabled at least by the use of an in-situ cable cleaner in conjunction with an ingot puller.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing [s] shall be interpreted as illustrative and not in a limiting sense.

What is claimed is:

1. An ingot puller apparatus for manufacturing a single crystal silicon ingot, the ingot puller apparatus comprising:
a crucible assembly for holding a silicon melt;
a crystal puller housing that defines a growth chamber, the crucible assembly being disposed within the growth chamber;
a pulling mechanism comprising a seed cable; and
a cleaning tool for cleaning the seed cable, the cleaning tool comprising:
a main body defining a slot that extends through the main body for receiving the seed cable;
a nozzle connected to the main body for directing a pressurized fluid at the seed cable; and
a discharge conduit connected to the main body for evacuating fluid discharged from the nozzle, wherein the main body is attached to the crystal puller housing.

2. The ingot puller apparatus of claim 1 further comprising a controller connected in communication with the cleaning tool and the pulling mechanism, wherein the controller is configured to:
control the cleaning tool to direct the pressurized fluid to the seed cable during a seed cable cleaning process; and
control the pulling mechanism to move the seed cable through the slot during the seed cable cleaning process.

3. The ingot puller apparatus of claim 1, wherein the main body is positioned longitudinally between the crucible assembly and the pulling mechanism.

4. The ingot puller apparatus of claim 1, wherein the main body is fixed in position on the housing.

5. The ingot puller apparatus of claim 1, wherein the crystal puller housing defines a pull chamber for removing a formed silicon ingot from the melt, and wherein the main body is attached to the pull chamber.

6. The ingot puller apparatus of claim 5, wherein the main body is positioned within the pull chamber.

7. The ingot puller apparatus of claim 5, wherein the nozzle and the discharge conduit are each in flow communication with the pull chamber.

8. The ingot puller apparatus of claim 1, wherein the main body has a disc shape and the nozzle is oriented perpendicular relative to the discharge conduit.

9. The ingot puller apparatus of claim 1, wherein the main body includes a first end wall, a second end wall, and a sidewall extending between the first end wall and the second end wall, the sidewall defining an outer periphery of the main body, wherein the seed cable extends through the first end wall and the second end wall adjacent the slot.

10. The ingot puller apparatus of claim 1, wherein the main body has a disc shape and the cleaning tool includes an additional nozzle connected to the main body and an additional discharge conduit, wherein the slot is defined at a radial center of the main body and each of the nozzle, the additional nozzle, the discharge conduit, and the additional discharge conduit are positioned on the main body to direct fluid flow therein in one or more radial directions across the main body.

11. The ingot puller apparatus of claim 10, wherein the additional nozzle is oriented in radial alignment with the nozzle and the additional discharge conduit is oriented in radial alignment with the discharge conduit.

12. The ingot puller apparatus of claim 1, wherein the main body includes a first end wall, a second end wall, and a sidewall extending between the first end wall and the second end wall, wherein the main body includes a radially extending first surface recessed from the first end wall, and wherein the nozzle and the first surface collectively define a supply channel through which the pressurized fluid is directed.

13. The ingot puller apparatus of claim 12, wherein a first section of the supply channel is defined within the nozzle and a second section of the supply channel is defined between the first surface and the nozzle, and wherein a cross-sectional area of the first section is greater than a cross-sectional area of the second section.

14. A method of cleaning a seed cable of an ingot puller apparatus comprising:
directing a pressurized fluid through a nozzle of a cleaning tool to the seed cable, wherein the cleaning tool includes a main body attached to a housing of the ingot puller apparatus and the nozzle is connected to the main body, the main body defining a slot that extends through the main body, the seed cable extending through the slot;
directing the fluid discharged from the nozzle to a discharge conduit connected to the main body; and
controlling a pulling mechanism of the ingot puller apparatus to move the seed cable through the slot for cleaning along a length of the seed cable.

15. The method of claim 14, wherein the cleaning tool is fixed to the housing and a crystal growing operation may be performed by the ingot puller apparatus without removing the cleaning tool from the housing.

16. The method of claim 14, wherein the housing defines a pull chamber for removing a formed single crystal silicon ingot from a melt, and wherein the main body is attached to the pull chamber.

17. The method of claim 16, wherein the nozzle and the discharge conduit are each in flow communication with the pull chamber.

18. The method of claim 14, wherein the main body has a disc shape and the cleaning tool includes an additional nozzle connected to the main body and an additional discharge conduit, wherein the slot is defined at a radial center of the main body and each of the nozzle, the additional nozzle, the discharge conduit, and the additional discharge conduit are positioned on the main body such that fluid flow therein is in one or more radial directions across the main body.

19. The method of claim 18, wherein the additional nozzle is oriented in radial alignment with the nozzle and the additional discharge conduit is oriented in radial alignment with the discharge conduit.

20. The method of claim 14 further comprising growing a single crystal silicon ingot from a silicon melt in a crucible assembly of the ingot puller apparatus, wherein the cleaning tool is positioned within the housing during growing of the ingot.
